(19) United States
(12) Patent Application Publication
(10) Pub. No.: US 2026/0130154 A1
(43) Pub. Date: May 7, 2026

(54) DETACHABLE PURIFIER AND SUPPLY SYSTEM COMPRISING THE SAME

(71) Applicant: Samsung Electronics Co., Ltd., Suwon-si (KR)

(72) Inventors: JIHWAN NOH, Suwon-si (KR); Jungwon Kim, Suwon-si (KR); YIGIL CHO, Suwon-si (KR); Sunghyeon Park, Suwon-si (KR); BUMSHIK KIM, Suwon-si (KR); YUNHO KIM, Suwon-si (KR); SeongBin Park, Suwon-si (KR); Jihong Park, Suwon-si (KR); Junsang Yun, Suwon-si (KR); SAMJONG CHOI, Suwon-si (KR)

(21) Appl. No.: 19/361,178

(22) Filed: Oct. 17, 2025

(30) Foreign Application Priority Data
Oct. 21, 2024 (KR) 10-2024-0144358
Dec. 16, 2024 (KR) 10-2024-0187246

(51) Int. Cl. H10P 72/00; B01D 53/26

(52) U.S. Cl. CPC H10P 72/0402; B01D 53/266

(57) ABSTRACT

A detachable purifier includes a compressor configured to pressurize a fluid, a buffer tank connected to the compressor, and configured to store the fluid, a particle filter connected to the buffer tank and configured to filter impurities in the fluid when the fluid passes through the particle filter; a dehumidifying filter connected to the buffer tank and configured to filter moisture within the fluid when the fluid passes through the dehumidifying filter; a first inlet pipe connected to the compressor and having a first removable connector for connection to a supply flow path; and a discharge pipe connected to the dehumidifying filter and having a second removable connector for connection to the supply flow path, and wherein the buffer tank is provided between the particle filter and the dehumidifying filter.

### CROSS-REFERENCE TO RELATED APPLICATION(S)

This U.S. non-provisional application claims priority under 35 USC § 119 to Korean Patent Application No. 10-2024-0144358, filed on Oct. 21, 2024, in the Korean Intellectual Property Office, the disclosure of which is herein incorporated by reference in its entirety.

### BACKGROUND

Various materials are used in a semiconductor fabrication plant to manufacture semiconductors. As some of materials are essential materials to manufacture semiconductors, their usage increases continually every year. However, some essential materials have limited production worldwide, and the limited production is concentrated in some countries. Therefore, there are problems such as increased costs for securing the essential materials and decreased supply stability. Accordingly, various studies are being conducted to reduce the usage of the essential materials during semiconductor manufacturing process and to recycle the essential materials used.

### SUMMARY

Example embodiments of the present disclosure provide a detachable purifier which can be coupled to and detached from a supply pipe in a semiconductor fabrication plant and a supply system comprising the same.

Example embodiments of the present disclosure provide a detachable purifier which is compact and a supply system comprising the same.

Example embodiments of the present disclosure provide a detachable purifier which can be moved in the semiconductor fabrication plant and a supply system comprising the same.

Example embodiments of the present disclosure provide a detachable purifier which can selectively be coupled to one of a plurality of supply pipes and a supply system comprising the same.

Example embodiments of the present disclosure provide a detachable purifier and a supply system comprising the same, with reduced power consumption.

Example embodiments of the present disclosure provide a detachable purifier with improved purification performance and a supply system comprising the same.

Example embodiments of the present disclosure provide a detachable purifier with improved durability and a supply system comprising the same.

Example embodiments of the present disclosure provide a detachable purifier which can be utilized together with existing equipment within the fabrication plant and a supply system comprising the same.

Example embodiments of the present disclosure provide a detachable purifier which can flexibly respond to and be applied to changes in production materials, production volume, or production facilities and a supply system comprising the same.

According to an example embodiment, a detachable purifier includes a compressor configured to pressurize a fluid, a buffer tank connected to the compressor and configured to store the fluid, a particle filter connected to the buffer tank and configured to filter impurities in the fluid when the fluid passes through the particle filter, and a dehumidifying filter connected to the buffer tank and configured to filter moisture within the fluid when the fluid passes through the dehumidifying filter; a first inlet pipe connected to the compressor and having a first r connector for removably connecting to a supply flow path; and a discharge pipe connected to the dehumidifying filter and having a second connector for removably connecting to the supply flow path, and wherein the buffer tank is provided between the particle filter and the dehumidifying filter.

According to an example embodiment, a supply system includes a supply pipe configured supply a fluid to the supply system, and a purifier configured to be detachably connected to the supply pipe, wherein the purifier comprises a compressor configured to pressurize the fluid supplied by the supply pipe, a buffer tank connected to the compressor and configured to store the fluid pressurized by the compressor, a particle filter connected to the buffer tank and configured to filter impurities in the fluid, and a dehumidifying connected to the buffer tank and configured to filter moisture within the fluid, and wherein the buffer tank is provided between the particle filter and the dehumidifying filter.

According to an example embodiments, a method of recovering process fluid includes providing a fluid at an initial pressure to an inlet of a semiconductor manufacturing process apparatus from an upstream fluid supply; performing a process by the semiconductor manufacturing process apparatus using the fluid and outputting used fluid from an outlet of the semiconductor manufacturing process apparatus; redirecting the used fluid output from the outlet of the semiconductor manufacturing process apparatus to an inlet pipe of a mobile purifier to introduce the used fluid into the mobile purifier; compressing the used fluid with the mobile purifier to a return pressure that is greater than the initial pressure of the fluid to produce a purified fluid; and returning purified fluid to the inlet of the semiconductor manufacturing process apparatus.

### BRIEF DESCRIPTION OF DRAWINGS

FIG. 1 is a perspective view of a detachable purifier according to an example embodiment.

FIG. 2 is a schematic diagram of a detachable purifier according to an example embodiment.

FIG. 3 is a schematic diagram of a detachable purifier according to an example embodiment.

FIG. 4 is a schematic diagram of a supply system comprising a detachable purifier according to an example embodiment.

FIG. 5 is an enlarged view of region S1 of FIG. 4.

FIG. 6 is a schematic diagram of a supply system comprising a detachable purifier according to an example embodiment.

### DETAILED DESCRIPTION

Hereinafter, example embodiments will be described with reference to the accompanying drawings. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

Hereinafter, embodiments in the example embodiment will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “connected” to another element” the elements are configured such that a liquid or gas can flow, or be passed, from one item to the other. For example, the elements may be connected through a conduit such as a pipe or hose may be present between the elements providing a path for the liquid or gas to flow from one element to another. In another example, the elements may be directly connected such that an opening of a first element corresponds to an opening of a second element such that the fluid may flow directly from the opening of the first element into the opening of the second element.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second”in the specification or another claim).

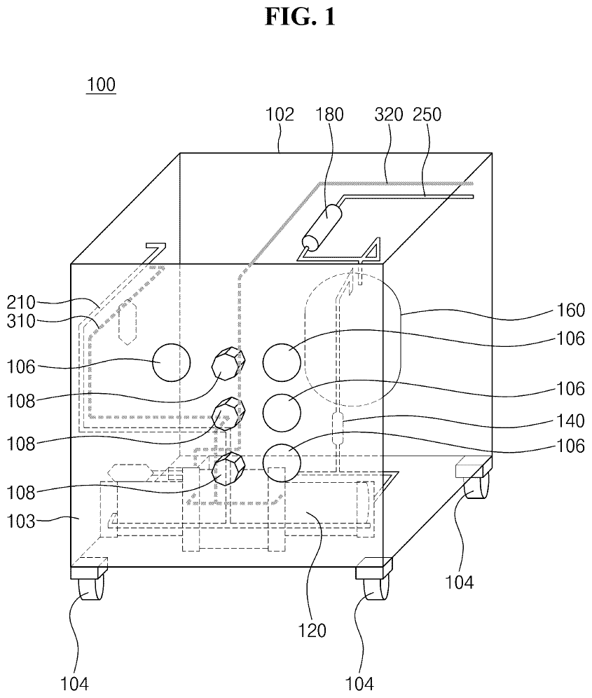

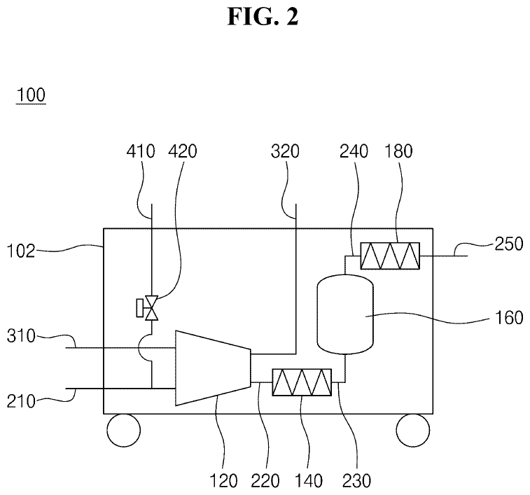

FIG. 1 is a perspective view of a detachable purifier according to an example embodiment. FIG. 2 is a schematic diagram of a detachable purifier according to an example embodiment.

Referring to FIG. 1 and FIG. 2, a detachable purifier 100 (hereinafter referred to as a “purifier”) may comprise a compressor 120, a buffer tank 160, a particle filter 140, and a dehumidifying filter 180. The particle filter 140 filters particles in a material (e.g., a fluid) passing therethrough. The dehumidifying filter 180 filters and/or removes moisture in the material. The material may refer to a material to be purified which passes through the purifier 100 such as a fluid (e.g., a gas or a liquid). The material may include a single-component material, a dual-component material, or a multi-component material.

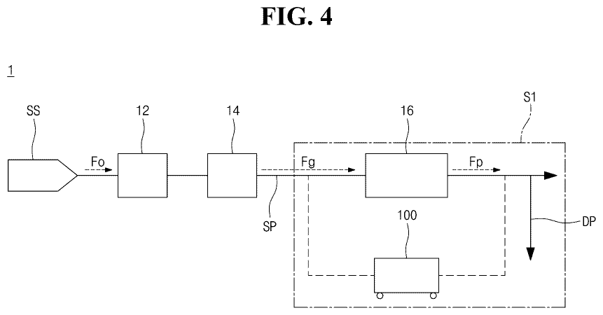

The compressor 120 may increase the pressure of the material introduced into the purifier 100. For example, the compressor may pressurize the material introduced into the purifier 100. In one embodiment, when the pressure of the material discharged from the purifier 100 is lower than the pressure of the material in a supply pipe SP (e.g., a supply pipe to another component such as a main purifier 16, which will be described in relation to FIG. 4), the compressor 120 may pressurize the material inside the purifier 100 to pressure that is the same or greater than the pressure of the material in the supply pipe SP. Through this, the pressure of the material discharged from the compressor 120 may be increased. Accordingly, the material discharged from the compressor 120 may be smoothly introduced into the supply pipe SP (e.g., may flow from the purifier 100 to the supply pipe SP).

The compressor 120 may pressurize the material inside the purifier 100 using various compression techniques. In embodiments, the compressor 120 may be one of the following types of compressors: diaphragm type, screw type, vane type, scroll type, centrifugal type, or axial type and may compress the material in a conventional manner. For example, the compressor 120 may be a diaphragm compressor.

The buffer tank 160 may store the material to be introduced into the purifier 100. The buffer tank 160 may be connected to the compressor 120. The buffer tank 160 may be provided downstream of the compressor 120. The material passing through the compressor 120 may be temporarily stored in the buffer tank 160. Through this, the purifier may discharge the material at a stable pressure.

In one embodiment, the material stored in the buffer tank 160 may be discharged when its volume is above a certain volume or its pressure is above a certain pressure. Through this, the purifier 100 may discharge the material at a consistent pressure.

The buffer tank 160 may be formed of metal or carbon. For example, the buffer tank 160 may be formed of stainless steel, nickel (Ni), chromium-molybdenum steel (Cr—Mo Steel), manganese steel (Mn steel), or carbon nanotube.

The particle filter 140 may filter particles inside the material (e.g., particles suspended in a fluid). The particles may refer to foreign substances, including fine dust and fine particles. The particle filter 140 may include materials such as polytetrafluoroethylene (e.g., Teflon), stainless steel, polymers, and nanofibers. The particle filter 140 may be one of the membrane type, cryogenic type, and/or adsorption type.

The particle filter may be connected to the compressor 120. The particle filter 140 may be connected to the buffer tank 160. In one embodiment, the particle filter 140 may be provided between the compressor 120 and the buffer tank 160. In one embodiment, the particle filter is provided downstream of the compressor 120, and upstream of the buffer tank 160. Through this, the particle filter 140 may filter particles generated from the compressor 120. Accordingly, a phenomenon of particles generated from the compressor 120 being introduced into the buffer tank 160 may be minimized (e.g., particles, including particles generated through the operation of the compressor may be filtered out of the material before entering the buffer tank 160).

The dehumidifying filter 180 may filter and/or remove moisture within the material. The dehumidifying filter 180 may remove moisture within the material before the material is discharged from the purifier 100. The dehumidifying filter 180 may be provided downstream of the compressor 120, the particle filter 140, and the buffer tank 160. Moisture adsorbed within the compressor 120, the buffer tank 160, and the pipes may be mixed within the material as the material passes through the purifier 100, increasing the moisture in the material. The dehumidifying filter 180 may remove the moisture within the material that may otherwise result from the material passing through the purifier 100.

The purifier may further comprise a frame 102. The frame 102 may have an opening in at least one direction. Through this opening, a connection between the supply pipe SP and pipes within the purifier 100 may be facilitated. The compressor 120 and the buffer tank 160 may be coupled to the frame 102.

A plurality of casters 104 may be coupled to the frame 102. The plurality of the casters 104 may be wheels coupled to the frame 102. The frame may be movable via the casters 104. For example, the purifier 100 may be a mobile purifier.

The purifier 100 may further comprise a panel 103 coupled to the frame 102 (e.g., a front panel). A plurality of measuring instruments 106 and control valves 108 may be installed on the panel 103. Each of the measuring instruments 106 may display a measurement of the pressure at a corresponding part inside the purifier 100 (e.g., each of the measuring instruments 106 may have an associated sensor that measures the pressure inside the corresponding part). Each of the control valves 108 may control the flow rate in a corresponding pipe inside the purifier 100.

The purifier 100 may include a plurality of pipes defining flow paths. In one embodiment, the purifier 100 may include a first inlet pipe 210 connected to the compressor 120. The first inlet pipe 210 may be connected to a supply flow path inside a semiconductor fabrication plant by a connector configured to be removably connected. For example, the connector may be a threaded pipe connection, a quick fit connection, or other connection such as those known in the art. Through this connection, the material discharged from the supply flow path may flow to the compressor 120 through the first inlet pipe 210.

Referring to FIG. 2, the purifier 100 may include a first connecting pipe 220 connecting the compressor 120 and the particle filter 140, a second connecting pipe 230 connecting the particle filter 140 and the buffer tank 160, and a third connecting pipe 240 connecting the buffer tank 160 and the dehumidifying filter 180.

The purifier 100 may include a discharge pipe 250 connected to the dehumidifying filter 180. The discharge pipe 250 may be connected to the supply flow path by a connector configured to be removably connected. For example, the connector may be a threaded pipe connection, a quick fit connection, or other connection such as those known in the art. Through this connection, purified material passing through the purifier 100 may be discharged to the supply flow path again through the discharge pipe 250.

The purifier 100 may further include a first outlet pipe 410 branched from the first inlet pipe 210, and an outlet valve 420 configured to control the flow rate of the first outlet pipe 410. When the outlet valve 420 is opened, the material introduced through the first inlet pipe 210 may be directly discharged through the first outlet pipe 410 without passing through the other components of the purifier 100. Conversely, when the outlet valve is closed, the material introduced through the first inlet pipe 210 may be introduced into the compressor 120.

The purifier 100 may further include a second inlet pipe 310 connected to the compressor 120 and a second outlet pipe 320. A driving fluid may be introduced into the compressor through the second inlet pipe 310, and discharged from the compressor 120 through the second outlet pipe 320. The driving fluid may be used for pressurizing operation of the compressor 120 (e.g., the driving fluid may spin a turbine to power the compressor 120). In one embodiment, the compressor 120 may pressurize the material passing through the compressor 120 using the driving fluid. For example, the driving fluid may include nitrogen gas.

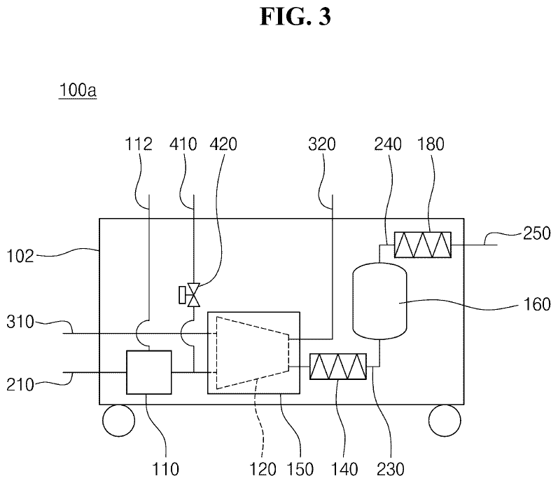

FIG. 3 is a schematic diagram of a detachable purifier according to an example embodiment.

Most of components of a purifier 100a described below and substances included within the components are the same as, substantially the same as, or similar to the components of the purifier 100 described above in FIG. 2. Therefore, for convenience, a description of components that would be duplicative may be omitted and the following explanation will focus on differences from the purifier 100 described above.

Referring to FIG. 3, the purifier 100a may further include a separator 110 configured to separate a portion of the material introduced into the purifier 100a and a separation pipe 112 through which separated portion is discharged. For example, the material introduced into the purifier 100a may be a mixed material that may be separated into individual materials.

The separator 110 may separate a specific material from the remaining materials among the material introduced into the purifier 100a. For example, the separator 110 may separate helium gas (He) from the remaining gases among a mixed gas introduced into the purifier 100a. Through this separation, the separator 110 may provide helium gas with increased purity to the compressor 120.

The separator 110 may separate the material in various ways. The separator 110 may be a conventional separator 110. For example, the separator 110 may be a membrane type separator.

The separator 110 may discharge separated remaining materials out of the purifier 100a through the separation pipe 112.

The purifier 100a may further include a cooler 150 configured to cool the compressor 120. As the compression ratio of the compressor 120 increases, the heat generation of the compressor 120 may increase. The cooler 150 may discharge heat generated from the compressor 120 to outside of the purifier 100a to cool the compressor 120. Through this cooling, the performance of the compressor 120 may be further improved, and the compressor 120 may operate at a higher pressure than would otherwise be possible. Accordingly, versatility of the purifier 100a may be enhanced.

The cooler 150 may include heat exchange fins coupled to the compressor 120 and airflow passing through the heat exchange fins may remove heat from the heat exchange fins. However, the cooler 150 is not limited thereto and may cool the compressor 120 using various methods, including conventional cooling techniques.

FIG. 4 is a schematic diagram of a supply system comprising a detachable purifier according to an example embodiment.

Referring to FIG. 4, the supply system 1 may include the supply pipe SP providing the supply flow path and the purifier 100, which is connectable and detachable to the supply pipe SP. The purifier 100 may be connected or detached from the supply pipe SP.

The supply pipe SP may be connected to a supply source SS. The material supplied from the supply source SS may flow Fo through the supply pipe SP. The supplied material may include a material used in semiconductor manufacturing (e.g., helium) and/or a material used in operating and managing a semiconductor facility (e.g., helium). The supply source SS may be a storage container (e.g., a tank of a fluid) or may be an inlet for receiving material (e.g., a fluid inlet receiving fluid transported from a container where the material is stored). The material supplied from the supply source SS may be referred to as a raw material. The raw material may be introduced into the supply system 1 through the supply pipe SP.

The supply system 1 may include a filtering device 12 provided on the supply pipe SP. The filtering device 12 may filter the raw material introduced into the supply pipe SP. This filtering process may be a primary filtering process. The raw material may be primarily filtered through the filtering device 12. The raw material, which has been filtered to increase its purity while passing through the filtering device 12, may be referred to as the primary filtered material.

The supply system 1 may further include an analysis device 14 provided on the supply pipe SP. The analysis device 14 may analyze the material inside the supply pipe SP (e.g., the primary filtered material). In one embodiment, the analysis device 14 may analyze components and concentration of the components of the material inside the supply pipe SP. The analysis device 14 may be provided downstream of the filtering device 12.

The supply system 1 may further include a main purifier 16, provided on the supply pipe SP. The primary filtered material may flow Fg into the main purifier 16. The main purifier 16 may further increase the purity of the primary filtered material inside the supply pipe SP (e.g., by removing particles suspended in the primary filtered material). For example, the main purifier 16 may include a porous filter adsorbing materials other than the primary filtered material (e.g., helium). The primary filtered material may be referred to as a secondary filtered material after passing through the main purifier 16. The secondary filtered material may be supplied Fp to semiconductor production lines. For example, the secondary filtered material may be provided to a plurality of process chambers through the supply pipe SP. Furthermore, the secondary filtered material, which has passed through the main purifier 16, may be used for semiconductor production or various other purposes.

The supply system 1 may include an emission pipe DP that branches from the supply pipe SP. Some or all of the secondary filtered material may be selectively discharged through the emission pipe DP from the supply pipe SP. For example, when the material is helium, excess helium supplied through the supply pipe SP may be discharged via the emission pipe DP.

In addition, when the supply system 1 is not required to supply the secondary filtered material to a process chamber, the material may be supplied by the supply source SS at a minimum flow rate for operating the supply system 1 normally. The material for the normal operation of the supply system 1 may be discharged to the outside of the supply system 1 through the emission pipe DP. For example, when helium is not required for a downstream process chamber, helium may be supplied from the supply source SS at a minimum flow rate for the operation of the analysis device 14 or the main purifier 16. The helium may then be discharged through the emission pipe DP rather than being delivered to a downstream process chamber. In addition, it may be necessary to purge the supply pipe SP with material. For example, helium may be supplied to purge the supply pipe SP and the helium supplied for purging the supply pipe SP may also be discharged through the emission pipe DP.

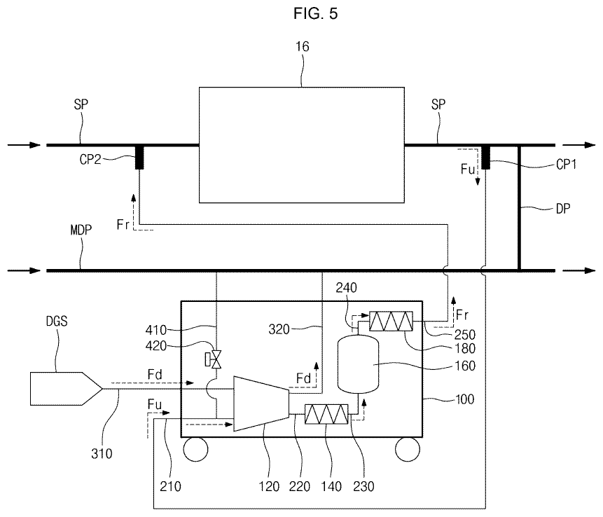

FIG. 5 is an enlarged view of region S1 of FIG. 4.

Referring to FIG. 4 and FIG. 5, the purifier 100 may be connected parallel to, but in a reverse direction with the main purifier 16 (e.g., connected in a serial loop). In one embodiment, the first inlet pipe 210 and the first outlet pipe 410 of the purifier 100 may be connected to the supply pipe SP upstream and downstream of the main purifier 16, respectively. In one embodiment, the first inlet pipe 210 of the purifier 100 may be connected to the supply pipe SP at a location downstream of the main purifier 16. Through this connection, the material discharged after passing through the main purifier 16 (e.g., the secondary filtered material) may flow to the purifier 100 (e.g., the secondary filtered material may be diverted from flowing to a process chamber and instead flow to the purifier 100). The discharge pipe 250 of the purifier 100 may be connected to the supply pipe SP at a location upstream of the main purifier 16. Through this connection, the material purified through the purifier 100 may be supplied again to the supply pipe SP at a location upstream of the main purifier 16 and then purified through the main purifier 16 again. These connections may be connected using connectors configured to be removably connected, as described previously.

In one embodiment, the supply pipe SP may include a first connecting portion CP1 to which the first inlet pipe 210 is connected. The first connecting portion CP1 may be provided downstream of the main purifier 16. The supply pipe SP may include a second connecting portion CP2 to which the discharge pipe 250 is connected. The second connecting portion CP2 may be provided upstream of the first connecting portion CP1. The second connecting portion CP2 may be provided upstream of the main purifier 16. Through this configuration, the material discharged downstream from the main purifier 16 may be supplied upstream back to the main purifier 16 through the purifier 100 (e.g., recycled to be used again).

In one embodiment, the first connecting portion CP1 may be connected to the emission pipe DP branching from the supply pipe SP. Through this connection, the purifier 100 may receive, purify, and resupply the material discharged from the primary purifier through the supply pipe SP. Accordingly, the purifier 100 may receive the material (e.g., helium gas), which is supplied at the minimum flow rate to maintain normal performance of the main purifier 16, purify the received material, and supply the purified material so that the purified material can be reused. In some examples, the purifier 100 may supply the purified material upstream of the main purifier 16 (e.g., to the supply pipe SP at a location upstream of the main purifier), and the purified material may be further purified while passing through the main purifier 16 again.

In one embodiment, the purifier 100 may be provided downstream of the analysis device 14. In one embodiment, the first inlet pipe 210 of the purifier 100 may be provided downstream of the analysis device 14. The discharge pipe 250 of the purifier 100 may be provided upstream of the main purifier 16. Through this arrangement, the purifier 100 may receive the material supplied at a minimum flow rate for normal operation of the analysis device 14, purify the received material, and supply the purified material so that the purified material can be reused.

The supply system 1 may include a main emission pipe MDP. The supply pipe SP may be connected to the main emission pipe MDP. For example, the emission pipe DP may branch from the supply pipe SP and may be connected to the main emission pipe MDP. At least a portion of the material inside the supply pipe SP may be discharged to the main emission pipe MDP through the emission pipe DP.

During operation of the purifier 100, the secondary filtered material in the supply pipe SP may flow Fu into the purifier 100 through the first inlet pipe 210 connected to the first connecting portion CP1.

When the secondary filtered material is not suitable for purification through the purifier 100, the outlet valve 420 may be opened. Accordingly, the secondary filtered material may be directly discharged into the main emission pipe MDP through the first outlet pipe 410.

When the secondary filtered material is suitable for purification through the purifier 100, the outlet valve 420 may be closed. Accordingly, the secondary filtered material may flow into the compressor 120 and the compressor 120 may pressurize the secondary filtered material.

To pressurize the secondary filtered material, a driving fluid may be provided to the compressor 120. The driving fluid may be introduced into the compressor 120 through the second inlet pipe 310 from a driving fluid supply source DGS. The driving fluid, which has passed the compressor, may be discharged to the main emission pipe MDP through the second outlet pipe 320.

The secondary filtered material discharged from the compressor 120 may flow into the particle filter 140 through the first connecting pipe 220. The particle filter 140 may filter the secondary filtered material to remove impurities that may have been introduced into the material. For example, the secondary filtered material may have impurities such as particles introduced into it through the compression process. For example, the particle filter 140 may filter particles from the secondary filtered material. The particles may include particles generated while passing through the supply pipe SP and particles generated while passing through the compressor 120. The material that has passed through the particle filter 140 may be referred to as a primary purified material.

The primary purified material may flow into the buffer tank 160 through the second connecting pipe 230. The primary purified material may be temporarily stored in the buffer tank 160. Through this arrangement, the purifier 100 may supply the primary purified material to the supply pipe SP at a stable flow rate.

The primary purified material temporarily stored in the buffer tank 160 may flow into the dehumidifying filter 180 through the third connecting pipe 240. The dehumidifying filter 180 may remove moisture within the primary purified material. The moisture may include moisture adsorbed on surfaces in the pipes, moisture adsorbed on surfaces in the buffer tank 160, and moisture generated while passing the compressor 120 (e.g., moisture generated when compressing the material). Through this, the purifier 100 may supply the primary purified material with a higher quality to the supply pipe SP (e.g., having a lower moisture content). The primary purified material that has passed through the dehumidifying filter 180 may be referred to as a final purified material.

The final purified material may be supplied Fr to the supply pipe SP again through the discharge pipe 250. The discharge pipe 250 may be connected to the second connecting portion CP2 provided upstream of the main purifier 16. Through the second connecting portion CP2, the final purified material may be supplied upstream of the main purifier 16 to pass through the main purifier 16 again. Accordingly, the purity of the final purified material may be further increased without the use of an additional purification device within the purifier 100.

To supply the final purified material to the supply pipe SP, the pressure of the final purified material in the discharge pipe 250 should be higher than the pressure of the material in the supply pipe SP (e.g., the primary filtered raw material). To achieve this, the compressor 120 may increase the pressure of the final purified material so that it is higher than the pressure of the material in the supply pipe SP.

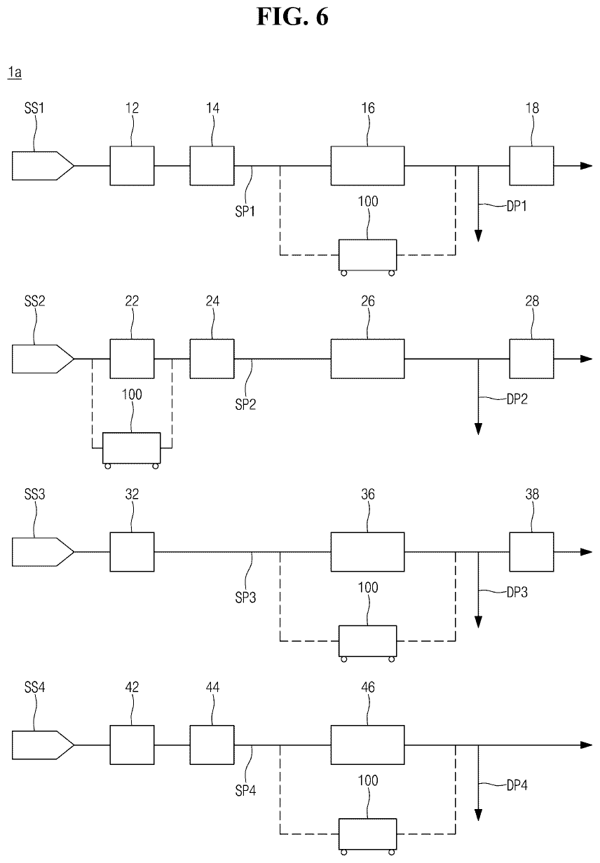

FIG. 6 is a schematic diagram of a supply system comprising a detachable purifier according to an example embodiment.

Referring to FIG. 6, the supply system 1a may include a plurality of supply pipes SP (e.g., first through fourth supply pipes SP1-SP4). Each of the supply pipes SP may be respectively connected to different supply sources SS (e.g., first through fourth supply sources SS1-SS4. Through the different supply pipes SP and supply sources SS, different materials from different supply sources SS may flow through each of the supply pipes SP. For example, the supply system 1a may include a first supply pipe SP1, a second supply pipe SP2, a third supply pipe SP3, and a fourth supply pipe SP4 defining different flow paths. A first material supplied from the first supply source SS1 may flow through the first supply pipe SP1, a second material supplied from the second supply source SS2 may flow through the second supply pipe SP2, a third material supplied from the third supply source SS3 may flow through the third supply pipe SP3, and a fourth material supplied from the fourth supply source SS4 may flow through the fourth supply pipe SP4.

The purifier 100 may be selectively connected to one of the supply pipes SP. For example, the purifier 100 may be selectively connected to one of the supply pipes SP to purify different materials. For example, the purifier 100 may be connected to one of the first to fourth supply pipes SP1, SP2, SP3, SP4.

When the supply pipe to which the purifier is connected is in an idle state, the purifier 100 may be detached from the idle supply pipe SP and connected to an operational supply pipe SP.

The supply system 1a may include a first filtering device 12 provided on the first supply pipe SP1, a first analysis device 14, a first main purifier 16, and a first additional analysis device 18. Here, the purifier 100 may be connected to the first supply pipe SP1 upstream and downstream of the first main purifier 16. The purifier 100 may supply the final purified material having substantially the same purity level as the primary filtered material (e.g., the purity level of material after passing through the first filtering device 12 to the first supply pipe SP1 in normal operation).

The supply system 1a may include a second filtering device 22 provided on the second supply pipe SP2, a second analysis device 24, a second main purifier 26, and a second additional analysis device 28. Here, the purifier 100 may be connected to the second supply pipe SP2 upstream and downstream of the second filtering device 22. Through this configuration, the purifier 100 may supply the final purified material having substantially the same purity level as the purity level of the raw material supplied to the second filtering device 22 to the second supply pipe SP2 in normal operation.

The supply system 1a may include a third filtering device 32 provided on the third supply pipe SP3, a third main purifier 36, and a third additional analysis device 38. The purifier 100 may be connected to the third supply pipe SP3 upstream and downstream of the third main purifier 36. For example, the purifier 100 may supply the final purified material having substantially the same purity level as the primary purified material after it has passed through the third filtering device 32 to the third supply pipe SP3 in normal operation.

The supply system 1a may include the fourth filtering device 42 provided on the fourth supply pipe SP4, a fourth analysis device 44, and a fourth main purifier 46. An additional analysis device may not be provided on the fourth supply pipe SP4. The purifier 100 may be connected to the fourth supply pipe SP4 upstream and downstream of the fourth main purifier 46. The purifier 100 may supply the final purified material having substantially the same purity level as the primary purified material after it has passed through the fourth filtering device 42 to the fourth supply pipe SP4 in normal operation.

In one embodiment, the filtering device, the main purifier, or the additional analysis device may not be provided on one of the supply pipes SP. In this case, the purifier 100 may be connected to one of the supply pipes to supply the final purified material having substantially the same level as the raw material to one of the supply pipes SP.

As a result, the purifier 100 may supply the final purified material to the supply pipe SP having the same purity level as the supply material normally supplied from upstream of the supply pipe SP.

In the detachable purifier and supply system comprising the same according to embodiments of the present disclosure, the supply system may purify the material within the supply pipe and resupply the purified material back to the supply pipe using a purifier detachably connected to the supply pipe. Accordingly, the total consumption of supply material may be reduced.

In addition, the purifier may be selectively connected to one of a plurality of supply pipes, so that the purifier may be detached from an idle supply pipe and connected to an in-use supply pipe. Through this selective connection, materials within the supply pipes may be recycled by installing a detachable purifier as needed, without requiring a separate purifier for each supply pipe. Accordingly, the purification system may be flexibly established and dismantled in response to changes in production materials, production volume, or manufacturing facilities.

In addition, the first inlet pipe of the purifier may be connected to the first connecting portion located downstream of the main purifier, so that the purifier may purify and recycle the material supplied at a minimum flow rate for the operation of the main purifier.

In addition, the discharge pipe of the purifier may be connected to the second connecting pipe located upstream of a main purifier, so that the purified material through the purifier may be further purified by the main purifier. Through this configuration, the purifier may utilize the existing main purifier and may not include a separate purifier. Through this configuration, a compact and movable purifier may be provided. In addition, the purifier with reduced power consumption may be provided.

In addition, the purifier may be located downstream of the analysis device, so the purifier may purify and recycle the material supplied at a minimum flow rate to prevent contamination of the analysis device.

In addition, the purifier may include the first outlet pipe branched from the first inlet pipe and the outlet valve controlling the flow rate of the first outlet pipe. The purifier may discharge directly into the main emission pipe as needed.

In addition, the particle filter may be provided between the compressor and the buffer tank to minimize the inflow of particles into the buffer tank. In one embodiment, particles may be generated during the physical operation of the compressor, and the particle filter may filter out the particles before the particles can enter the buffer tank. Through this filtering, damage to the buffer tank caused by particles may be reduced. Consequently, the purifier with improved durability may be provided.

In addition, the dehumidifying filter may be located downstream of the buffer tank, allowing the dehumidifying filter to remove the moisture from the purified material discharged from the purifier. In one embodiment, the dehumidifying filter may minimize the inflow of moisture into the supply pipe, which may have been adsorbed within the piping of the purifier, the compressor, and the buffer tank.

In addition, the purifier may include the separator connected to the first inlet pipe and the separation pipe for discharging the material separated by the separation device. Therefore, the purifier may separate and purify a desired material from a mixed material within the supply pipe.

In addition, a compact purifier may be provided as a purifier including a diaphragm or membrane type compressor, which may be driven by a driving gas source.

In addition, the purifier may include a frame having the plurality of the casters to provide a mobile purifier.

While example embodiments have been shown and described above, it will be apparent to those skilled in the art that modifications and variations could be made without departing from the scope of the present invention as defined by the appended claims.

What is claimed is:

1. A detachable purifier comprising:
a compressor configured to pressurize a fluid;
a buffer tank connected to the compressor and configured to store the fluid;
a particle filter connected to the buffer tank and configured to filter impurities in the fluid when the fluid passes through the particle filter;
a dehumidifying filter connected to the buffer tank and configured to filter moisture within the fluid when the fluid passes through the dehumidifying filter;
a first inlet pipe connected to the compressor and having a first connector removably connecting to a supply flow path; and
a discharge pipe connected to the dehumidifying filter and having a second connector for removably connecting to the supply flow path, and
wherein the buffer tank is provided between the particle filter and the dehumidifying filter.

2. The detachable purifier of claim 1, wherein
the dehumidifying filter is located downstream of the buffer tank.

3. The detachable purifier of claim 2, wherein
the particle filter is provided between the compressor and the buffer tank.

4. The detachable purifier of claim 3, wherein
the particle filter is located downstream of the compressor and upstream of the buffer tank.

5. The detachable purifier of claim 1, further comprising:
a separator connected to the first inlet pipe and configured to separate a secondary material from the fluid; and
a separation pipe configured to discharge the secondary material separated by the separator.

6. The detachable purifier of claim 1, further comprising:
a first outlet pipe branched from the first inlet pipe; and
an outlet valve configured to control flow rate of the first outlet pipe.

7. The detachable purifier of claim 1, wherein
the compressor configured to pressurize the fluid using a diaphragm type compressor.

8. The detachable purifier of claim 7, further comprising:
a second inlet pipe connected to the compressor and configured to provide a driving fluid to the compressor to drive the compressor; and
a second outlet pipe configured to receive the driving fluid discharged from the compressor.

9. The detachable purifier of claim 1, further comprising:
a frame having a plurality of casters.

10. A supply system comprising:
a supply pipe configured to supply a fluid to the supply system; and
a purifier configured to be detachably connected to the supply pipe;
wherein the purifier comprises:
a compressor configured to pressurize the fluid supplied by the supply pipe;
a buffer tank connected to the compressor and configured to store the fluid pressurized by the compressor;
a particle filter connected to the buffer tank and configured to filter out impurities in the fluid; and
a dehumidifying filter connected to the buffer tank and configured to filter out moisture within the fluid, and
wherein the buffer tank is provided between the particle filter and the dehumidifying filter.

11. The supply system of claim 10, wherein
the supply pipe is a first supply pipe of a plurality of supply pipes, and
the purifier is configured to be selectively connected to one of the plurality of the supply pipes.

12. The supply system of claim 10, further comprising:
a main purifier provided on the supply pipe and configured to purify the fluid,
wherein the purifier is configured to be connected in a loop with the main purifier.

13. The supply system of claim 12, wherein
the purifier further comprises:
a first inlet pipe connected to the compressor, and configured to be connected to the supply pipe; and
a discharge pipe connected to the dehumidifying filter, and configured to be connected to the supply pipe, and
the first inlet pipe is configured to be connected to a first connecting portion located downstream of the main purifier, and
the discharge pipe is configured to be connected to a second connecting portion located upstream of the main purifier.

14. The supply system of claim 13, further comprising:
a filtering device configured to be connected to the supply pipe and configured to filter a portion of the fluid supplied from a supply source, and
wherein the first connecting portion is located between the filtering device and the main purifier.

15. The supply system of claim 13, further comprising:
an analysis device configured to analyze the fluid supplied from a supply source,
wherein the purifier is located downstream of the analysis device.

16. The supply system of claim 13, further comprising:
a main emission pipe connected to the supply pipe,
wherein
the purifier further comprises:
a second inlet pipe connected to the compressor, and configured to provide a driving fluid to flow into the compressor; and
a second outlet pipe configured to discharge the driving fluid from the compressor, and
the second outlet pipe is configured to be connected to the main emission pipe.

17. The supply system of claim 16, wherein
the purifier further comprises:
a first outlet pipe branched from the first inlet pipe; and
an outlet valve configured to control flow rate of the first outlet pipe, and
the first outlet pipe is configured to be connected to the main emission pipe.

18. The supply system of claim 10, wherein
the dehumidifying filter is located downstream of the buffer tank.

19. The supply system of claim 18, wherein
the particle filter is provided between the compressor and the buffer tank.

20. A method of recovering process fluid comprising:
providing a fluid at an initial pressure to an inlet of a semiconductor manufacturing process apparatus from an upstream fluid supply;
performing a process by the semiconductor manufacturing process apparatus using the fluid and outputting used fluid from an outlet of the semiconductor manufacturing process apparatus;
redirecting the used fluid output from the outlet of the semiconductor manufacturing process apparatus to an inlet pipe of a mobile purifier to introduce the used fluid into the mobile purifier;
compressing the used fluid with the mobile purifier to a return pressure that is greater than the initial pressure of the fluid to produce a purified fluid; and
returning purified fluid to the inlet of the semiconductor manufacturing process apparatus.
